(19) United States
(12) Patent Application Publication
(10) Pub. No.: US 2004/0070945 A1
(43) Pub. Date: Apr. 15, 2004

(54) Heat dissipation structures and method of making

(76) Inventor: Wayne Rowland, Rochester, WA (US)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 10/454,755

(22) Filed: Jun. 3, 2003

Related U.S. Application Data
(60) Provisional application No. 60/386,616, filed on Jun. 5, 2002.

(51) Int. Cl. H05K 7/20

(52) U.S. Cl. 361/705

(57) ABSTRACT

A method and related structure for dissipating heat, particularly in electronic components. The method includes mixing magnetite particles and epoxy into a paste-like state, subjecting the mixture to opposing polarities of a magnetic field on opposing sides of the mixture until the epoxy hardens to urge the magnetite particles into alignment and to form elongate structures to conduct heat away from a heat source, such as an electronic component on which the epoxy is applied.

### CROSS-REFERENCE TO RELATED APPLICATION

This application claims the benefit of U.S. Provisional Patent Application No. 60/386,616 filed Jun. 5, 2002, where this provisional application is incorporated herein by reference in its entirety.

### BACKGROUND OF THE INVENTION

1. Field of the Invention

The present invention pertains to heat sinks and, more particularly, to methods and devices for dissipating heat and techniques of making the same.

2. Description of the Related Art

Electronic components, such as coils, motors, generators, capacitors, and integrated circuits generate heat when conducting electricity. Excessive heat can degrade performance and damage the component and nearby circuits. In extreme circumstances, fire will result, causing destruction of the device in which the component is housed as well as endangering nearby structures and life.

With respect to integrated circuits, the trend in electronic packaging is to continuously reduce size while increasing performance, both of which contribute to heat generation and heat density. Because of increasing heat densities, thermal management is given one of the highest priorities in the design cycle. To achieve the goal of avoiding soft failures, and short-term or long-term hard failures, heat generation and heat dissipation must be controlled such that reliability of the electronic component is maintained.

Two main principles are implemented in cooling components on a PC board, heat convection and heat conduction. In the first method, the heat load generated by the components' dissipation is directly transferred from the components and the board to a cooling fluid according to various thermal transfer modes, such as radiation and free convection in the air, or by forced convection with the air.

In the second method, the heat load is conducted from the components to the PC board, then to a heat exchanger, and then they are rejected to a fluid. In this case, the exchanger can be secured at the board ends or directly onto the entire rear face of the board. To minimize the board's thermal resistance, the board can be fitted with a thermal drain heat pipe. Alternatively, the heat is transferred from the components via high thermal conductivity materials to the module shell and then to a gas or liquid coolant via the heat exchanger surface. On the board itself, the thermal transfer mode is conduction.

Of all these techniques, the most widespread is direct air cooling. Air is available on most platforms, it is simple to implement, and it does not require complex and expensive sealing devices. The current design approach to thermal management is to use air-cooled systems as long as possible rather than be forced to apply more costly and elaborate fluid-based thermal systems. This can only be done by achieving higher levels of efficiency in the heat path from the semiconductor to the air. However, the disadvantages include mechanical and reliability issues inherent in such interfaces. In addition, this approach does not address the need for heat conduction in the electronic components themselves.

An example of one method of heat dissipation is illustrated in FIG. 1. Shown therein is a chip 10 mounted to a PC board 12. Associated with the chip 10 and the board 12 is a heat sink device 14. The heat sink device 14 has the disadvantage of occupying space and increasing the weight of the overall component. In addition, manufacturing and raw goods costs are higher.

Thermal management becomes critical when chips are bonded to other structures, as in chip-on-board, chip-on-chip, chip-on-flex, and multi-chip module configurations. While the heat conductivity of most epoxies has been sufficient for micro-bonding applications in the past, the increasing heat densities of integrated circuits requires more advanced techniques for cooling of integrated components as well as other discrete components, such as motor windings and the like.

### BRIEF SUMMARY OF THE INVENTION

In accordance with the disclosed embodiments of the invention, techniques and devices for heat dissipation are provided, particularly for electronic components, although the methodologies will have application outside the electronics field.

In one embodiment of the invention, a method of providing a heat dissipation structure is provided that includes forming a mixture of non-electrically conducting magnetite particles and epoxy; and subjecting the mixture to a magnetic field to cause the magnetite particles to connect and align into elongate heat conductive structures. The magnetic field may be induced via electric current passing through a coil or it may be applied by placing magnets with opposite poles at opposing sides or ends of the mixture.

In another embodiment of the invention, the mixture of magnetite particles and epoxy is applied to an integrated circuit, subjected to a magnetic field before the epoxy hardens, and then allowing the epoxy to harden.

In accordance with yet another aspect of the invention, the mixture of magnetite particles and epoxy is applied to the windings of a coil, then subjected to a magnetic field, and then allowed to solidify. Ideally, the mixture is applied to each and every set of windings.

Many other embodiments or applications of the methods and techniques of the present invention are possible, and in particular use as a heat sink or means of dissipating heat.

### BRIEF DESCRIPTION OF THE DRAWINGS

The foregoing features and advantages of the disclosed embodiments of the invention will be more readily appreciated as the same become better understood from the following detailed description when taken in conjunction with the accompanying drawings where:

FIG. 1 is an isometric projection of a known heat sink in combination with an integrated circuit;

FIGS. 2A-2C are block diagram representations of a method in accordance with one embodiment of the invention;

FIG. 3 is an illustration of a motor coil formed in accordance with the present invention; and

FIG. 4 is an illustration of a chip-on-chip structure formed in accordance with the present invention.

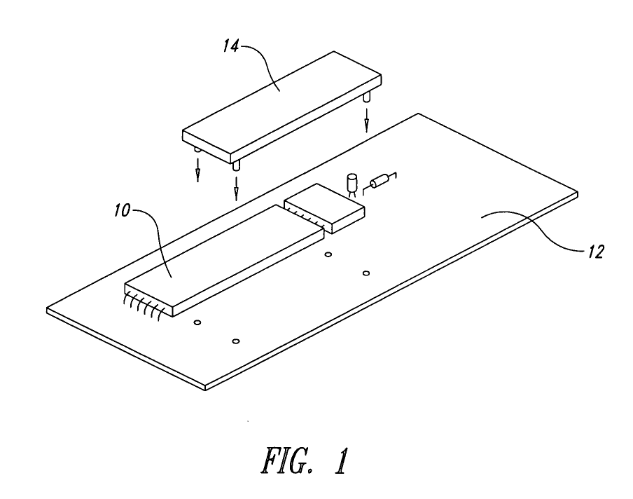

### DETAILED DESCRIPTION OF THE INVENTION

The methods and related devices formed in accordance with the disclosed embodiments of the invention will now be described in detail below. It is to be understood that while the invention will be described in the context of electronic components, it will have broader application, and as such is not to be limited to the following representative embodiments.

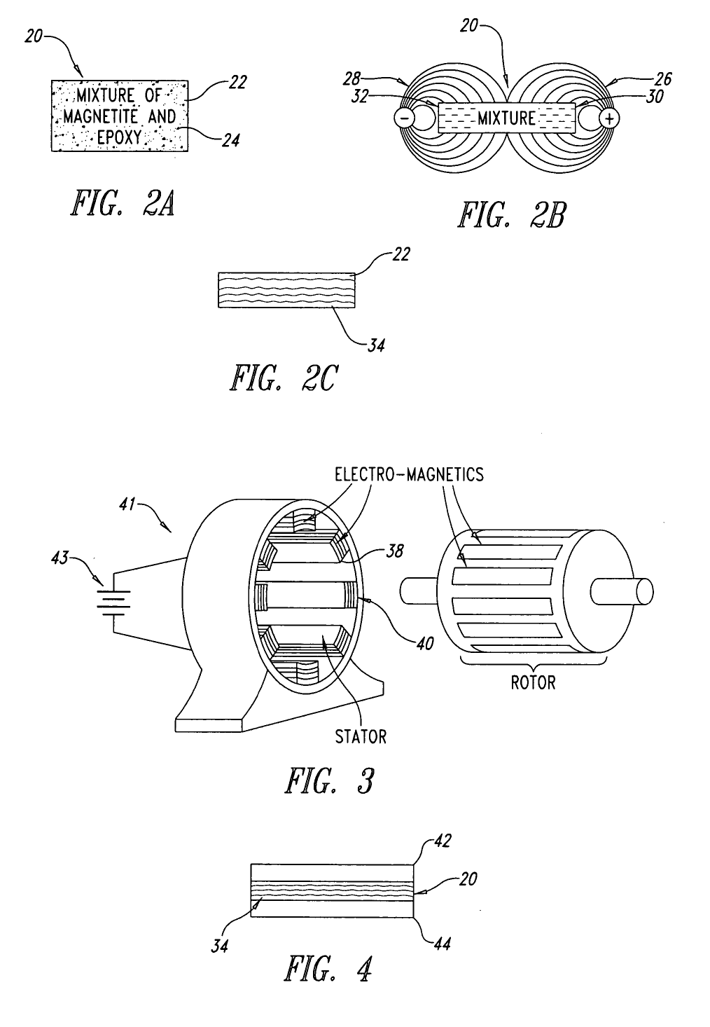

Referring initially to FIGS. 2A-2C, shown therein in block representation is the procedure for forming high thermal conductivity epoxy in accordance with one embodiment of the invention. Initially, a mixture 20 of epoxy 22 and magnetite particles 24 is formed as shown in FIG. 2A. The magnetite particles 24 are randomly distributed throughout the epoxy 22. Before the epoxy 22 hardens, the mixture 20 is subjected to a magnetic field wherein opposite poles are placed on opposite sides of the mixture 20. More particularly, a positive magnetic field 26 and a negative magnetic field 28 are positioned on opposite sides 30,32 of the mixture as shown in FIG. 2B, and they are preferably spaced equidistantly from each side 30, 32 of the mixture 20.

Application of the magnetic fields 26, 28 may be done by using permanent magnets or by induced magnetic fields, such as electromagnetism. For example, a coil energized by electricity may be used to generate the positive and negative fields.

Because the magnetite responds to the influence of the magnetic field, each particle 24 aligns itself with the lines of magnetic flux. In addition, the particles 24 align themselves with each other and come into contact with adjacent particles 24. The magnetic fields are continuously applied until the epoxy 22 hardens, holding the magnetite particles 24 in a new orientation. A shown in FIG. 2C, the magnetite particles 24 form elongate structures 34. These elongate structures 34 are outstanding thermal conductors, dissipating heat at a much faster rate than when the magnetite particles are randomly distributed throughout the mixture 20. When in use, and in order to remove the dissipated heat from the area, a conventional fan can be used to blow the heated air away from the structure.

The magnetite particles 24 are available in natural deposits in the form of FE₃O₄, and they are available from the inventor, although it is possible such particles 24 may be manufactured in the laboratory. It is a common material or compound used in the iron manufacturing process. Ideally, the magnetite should have a particle size in the range of 50-200 micrometers, and while it should be as pure as possible, it may include traces of other elements, such as titanium, silicon, and even quartz and silicon oxide. XRD analysis shows that the magnetite used in the present invention should have a normal spinel crystal structure. It should respond to a magnetic field yet have a low remnant magnetization.

The epoxy is readily commercially available and will not be described in detail herein. In a preferred embodiment, epoxy available on the commercial market in the form of 3M Scotch Weld #2216B/A translucent epoxy adhesive was found to work best. This particular form of epoxy comes in two cans, parts A and B, that are mixed together as instructed by the manufacturer. A 50% amount of magnetite powder is added and mixed well.

FIG. 3 illustrates an application of the present invention in cooling a field coil 40 for an electric motor 41. The mixture 20 of epoxy 22 and magnetite particles 24 (shown in FIGS. 2A-2C) is applied to the wire 38 as it is wound into the coil 40. A DC current from a DC voltage source 43 is passed through the coil 40 after it is wound and before the epoxy 22 hardens. Ideally a voltage of at least 12 volts is applied to the coil 40. After the epoxy has hardened, the current is removed.

FIG. 4 illustrates yet another embodiment of the invention wherein a pair of semiconductor chips 42, 44 having integrated circuits (not shown) formed thereon are adhered together with the mixture 20 of magnetite particles 24 and epoxy 22. More particularly, the mixture 20 is applied to the first chip 42 and the second chip 44 is applied to the mixture 20. While the mixture 20 has not hardened, the magnetic fields are applied to the chips 42, 44 and the mixture 20 as shown and described above in connection with FIGS. 2A-2C. Once the mixture 20 has hardened, the magnetic fields are removed and the chip-on-chip structure is ready for mounting to a PC board or other supporting structure.

As previously described, the magnetic fields applied to the chip-on-chip structure are generated either by permanent magnets or by electrically induced or enhanced magnetic fields. Alignment of the magnetic fields is done in a manner known to those skilled in the art so that the elongate structures 34 conduct the heat away from the heat source.

Electromagnets may be formed using the teachings herein that have superior heat dissipation and enhanced current and voltage generation characteristics. For example, a solid core of non-magnetizable steel, which is readily commercially available is provided. A winding of wire is wrapped with wire, then coated with the mixture 20, and magnetized as described above while the epoxy fills the spaces between the wires and hardens. Subsequent windings are added, each subsequent winding coated with epoxy and hardened while subjected to a magnetic field. Alternatively, if there is sufficient time, the windings can all be applied and individually coated as they are applied then subjected to a magnetic field as the mixture hardens.

Although representative embodiments of the invention have been illustrated and described, it is to be understood that various changes may be made therein without departing from the spirit and scope of the invention. Hence, the invention is not to be limited except by the scope of the appended claims and the equivalents thereof.

1. A method of providing a heat dissipating structure, comprising:
forming a mixture of magnetite particles and epoxy; and
subjecting the mixture to a magnetic field to cause the magnetite particles to connect and align into elongate heat conductive structures.

2. The method of claim 1 wherein subjecting the mixture to a magnetic field comprises passing an electric current through a coil to create the magnetic field.

3. The method of claim 1 wherein subjecting the mixture to a magnetic field comprises placing opposite poles of magnets on opposing sides of the mixture of magnetite particles and the epoxy.

4. A method of forming a heat dissipating coil, comprising:
forming a mixture of magnetite particles and epoxy;
applying the mixture to an electronic component;
subjecting the mixture of the magnetite particles and the epoxy to a magnetic field before the epoxy dries to form elongate heat conducting structures of the magnetite particles; and
maintaining the magnetic field until the epoxy hardens.

5. The method of claim 4 wherein applying the magnetic field comprises passing an electric current through a coil to induce the magnetic field.

6. The method of claim 4, wherein applying the magnetic field comprises placing opposite magnetic poles at opposing sides of the electronic structure.

7. An electronic device, comprising:
an electronic component; and
an epoxy compound form of an epoxy and magnetite particles applied to the electronic component, the magnetite particles formed into heat conducting structures in the epoxy to conduct heat generated by the electronic component.

8. The device of claim 7 wherein the electronic component comprises a coil, and the epoxy compound is applied to the coil.

9. The device of claim 7 wherein the electronic component comprises an integrated circuit and the epoxy compound is applied to the integrated circuit.

10. The device of claim 7 wherein the electronic component comprises a semiconductor chip and the epoxy compound is applied to the semiconductor chip.
